(19) United States
(12) Patent Application Publication
(10) Pub. No.: US 2014/0353820 A1
(43) Pub. Date: Dec. 4, 2014

(54) SEMICONDUCTOR DEVICE AND METHOD FOR FABRICATING THE SAME

(71) Applicant: Samsung Electronics Co., Ltd., Suwon-si (KR)

(72) Inventors: Sung-Hun Yu, Seoul (KR); Sang-Hoon Park, Hwaseong-si (KR); Jun-Gu Kang, Hwaseong-si (KR); Oh-Kyum Kwon, Suwon-si (KR); Sun-Hyun Kim, Anyang-si (KR)

(73) Assignee: Samsung Electronics Co., Ltd., Suwon-si (KR)

(21) Appl. No.: 14/199,539

(22) Filed: Mar. 6, 2014

(30) Foreign Application Priority Data
Jun. 3, 2013 (KR) 10-2013-0063567

(51) Int. Cl. H01L 23/00

(52) U.S. Cl. CPC H01L 24/13
USPC 257/737

(57) ABSTRACT

Semiconductor device and method for fabricating the same are provided. The semiconductor device comprises a first metal wiring line, a chip pad which is electrically connected with the first metal wiring line and has a first width, a passivation layer which encloses the chip pad and includes a contact hole, a first barrier pattern formed on a side wall of the contact hole and a top surface of the passivation layer, a contact filling the contact hole on the first barrier pattern, and a bump, which is formed of the same material as the contact, has a second width which is smaller than the first width, and is overlaid with the first metal wiring line and the chip pad, the bump being entirely overlapped with the chip pad.

### CROSS-REFERENCE TO RELATED APPLICATION

This application claims priority from Korean Patent Application No. 10-2013-0063567 filed on Jun. 3, 2013 in the Korean Intellectual Property Office, and all the benefits accruing therefrom under 35 U.S.C. 119, the contents of which are herein incorporated by reference in their entirety.

### TECHNICAL FIELD

The present invention relates to a semiconductor device and a method for fabricating the same. In particular, the present invention relates to a semiconductor device and a method to reduce or remove a dimple phenomenon and/or reduce a thickness of a semiconductor pad.

### BACKGROUND

Recently, semiconductor devices are becoming lighter, thinner, shorter, and overall smaller. At the same time, the semiconductor devices are being designed so as to implement various functions in one chip, wherein the number of external terminals which connect such a semiconductor device with an external device are also increased.

Even though the size of the semiconductor device is reduced, therefore, the number of external terminals which are formed in the semiconductor device is increased, so that it is important to efficiently faun the external terminal in a limited space of the semiconductor device.

### SUMMARY

The present invention has been made in an effort to provide a semiconductor device to which an electroplating method and a chemical mechanical polishing method are applied to remove a dimple phenomenon and reduce a size and a thickness thereof.

The present invention has been made in an effort to further provide a method for fabricating a semiconductor device which fabricates the semiconductor device.

The problems to be solved for this application are not limited to the aforementioned technical problems, and other technical problems, which have not been mentioned, may be understood by a person with ordinary skill in the art from the following description.

In one aspect of the present invention, there is provided a semiconductor device comprising a first metal wiring line, a chip pad which is electrically connected with the first metal wiring line and has a first width, a passivation layer which encloses the chip pad and includes a contact hole, a first barrier pattern formed on a side wall of the contact hole and a top surface of the passivation layer, a contact filling the contact hole on the first barrier pattern, and a bump which is formed of the same material as the contact, has a second width which is smaller than the first width, and is overlaid with the first metal wiring line and the chip pad, the bump being entirely overlapped with the chip pad.

In another aspect of the present invention, there is provided a semiconductor device comprising a device pattern, a first metal wiring line and a second metal wiring line which are disposed on the device pattern and formed at the same level, a chip pad which is electrically connected with the first metal wiring line, has a first width, and has a flat top surface, a third metal wiring line which is electrically connected with the second metal wiring line and formed at the same level as the chip pad, and a bump which is electrically connected with the chip pad, has a second width which is smaller than the first width, and is overlapped with the first metal wiring line and the chip pad.

In accordance with another aspect of the invention, there is provided a semiconductor device, comprising: a first metal wiring line; a chip pad electrically connected with the first metal wiring line and having a first width; a passivation layer that encloses the chip pad and includes a contact hole; a first barrier pattern formed on a side wall of the contact hole and a top surface of the passivation layer; a contact filling the contact hole on the first barrier pattern; and a bump which is formed of the same material as the contact, wherein the bump has a second width which is smaller than the first width, and is overlaid with the first metal wiring line and the chip pad, the bump being entirely overlapped by the chip pad.

In various embodiments, a profile of a side wall of the first barrier pattern can be connected with a profile of a side wall of the bump.

In various embodiments, the bump and the contact can include gold.

In various embodiments, the semiconductor device can further comprise a second metal wiring line formed at the same level as the first metal wiring line and a third metal wiring line formed at the same level as the chip pad. The third metal wiring line can be electrically connected with the second metal wiring line.

In various embodiments, the semiconductor device can further comprise a device pattern formed below the first metal wiring line and the second metal wiring line, wherein the second metal wiring line can be a power supply wiring line supplying a power to the device pattern.

In various embodiments, the passivation layer can include a lower passivation layer and an upper passivation layer sequentially laminated on the first metal wiring line, and the chip pad can be formed in the lower passivation layer and the contact hole can be formed in the upper passivation layer.

In various embodiments, a top surface of the lower passivation layer and a top surface of the chip pad can be coplanar.

In various embodiments, the first metal wiring line and the chip pad can be formed of different materials from each other.

In various embodiments, the first metal wiring line can include copper (Cu) and the chip pad can include aluminum (Al).

In accordance with another aspect of the invention, there is provided a semiconductor device, comprising: a device pattern; a first metal wiring line and a second metal wiring line which are disposed on the device pattern and formed at the same level; a chip pad which is electrically connected with the first metal wiring line, has a first width, and has a flat top surface; a third metal wiring line which is electrically connected with the second metal wiring line and formed at the same level as the chip pad; and a bump which is electrically connected with the chip pad, has a second width which is smaller than the first width, and is overlapped by the first metal wiring line and the chip pad.

In various embodiments, the second metal wiring line can be a power supply wiring line supplying a power to the device pattern.

In various embodiments, the semiconductor device can further comprises an upper passivation layer disposed on the chip pad and the third metal wiring line, wherein the bump can protrude from the upper passivation layer.

In various embodiments, the semiconductor device can further comprise a contact interposed between the chip pad and the bump, wherein the contact can be formed in the upper passivation layer and the contact and the bump can be formed at the same level.

In various embodiments, the bump and the contact can be formed of gold.

In accordance with another aspect of the invention, there is provided a method of making a semiconductor device, comprising: forming a first metal wiring line; forming a chip pad electrically connected with the first metal wiring line and having a first width; forming a passivation layer that encloses the chip pad and includes a contact hole; forming a first barrier pattern formed on a side wall of the contact hole and a top surface of the passivation layer; filling the contact hole on the first barrier pattern to form a contact; and forming a bump on the contact, the bump having a second width which is smaller than the first width, and is overlaid with the first metal wiring line and the chip pad, the bump entirely overlapped by the chip pad.

In various embodiments, the bump and the contact can be made of the same material.

In various embodiments, a profile of a side wall of the first barrier pattern can be connected with a profile of a side wall of the bump.

In various embodiments, the bump and the contact can include gold.

In various embodiments, the method can further comprise forming a second metal wiring line at the same level as the first metal wiring line and forming a third metal wiring line at the same level as the chip pad. The third metal wiring line can be electrically connected with the second metal wiring line.

In various embodiments, the method can further comprise forming a device pattern below the first metal wiring line and the second metal wiring line, wherein the second metal wiring line can be a power supply wiring line supplying a power to the device pattern.

In accordance with aspects of the present invention, there is a semiconductor device as shown in the figures.

In accordance with aspects of the present invention, there is a method of making a semiconductor device as shown in the figures.

### BRIEF DESCRIPTION OF THE DRAWINGS

The above and other features and advantages of the present invention will become more apparent by describing in detail embodiments thereof with reference to the attached drawings, in which:

FIG. 1 is a cross-sectional view illustrating a first embodiment of a semiconductor device, according to aspects of the present invention;

FIG. 2 is a cross-sectional view illustrating a second embodiment of a semiconductor device, according to aspects of the present invention;

FIG. 3 is a cross-sectional view illustrating a third embodiment of a semiconductor device, according to aspects of the present invention; and

FIGS. 4 to 10 are diagrams illustrating an embodiments of intermediate processes of a method for fabricating a semiconductor device, according to aspects of the present invention.

### DETAILED DESCRIPTION OF THE EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. With reference to the drawings, like reference numerals refer to like elements throughout the specification, unless otherwise indicated.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein with reference to cross-section illustrations are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

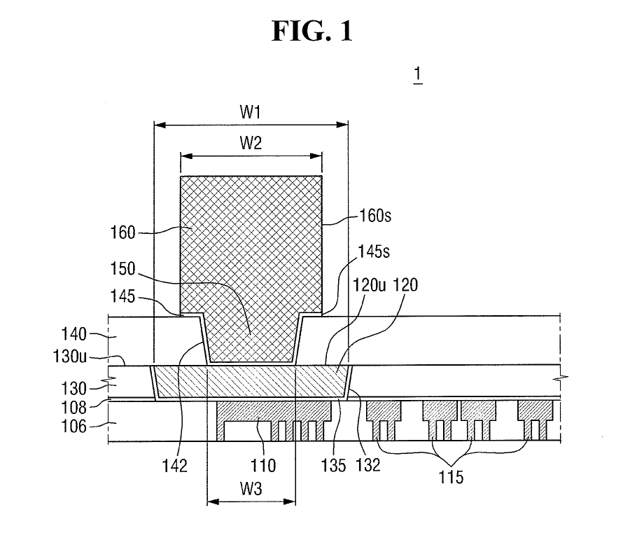

Hereinafter, a first embodiment of a semiconductor device according to aspects of the present invention will be described with reference to FIG. 1.

FIG. 1 is a cross-sectional view illustrating a semiconductor device according to a first embodiment of the present invention. Referring to FIG. 1, in this embodiment a semiconductor device 1 includes a first metal wiring line 110, a chip pad 120, a second barrier pattern 145, a contact 150, and a bump 160.

The first metal wiring line 110 may be formed in an interlayer insulating layer 106, which can be formed on a substrate. The first metal wiring line 110 may be electrically connected with a device pattern, which can also be formed on the substrate. The first metal wiring line 110 may supply, for example, an electrical signal to the device pattern or supply power to the device pattern. An interlayer insulating layer 106 may include or be formed from, for example, at least one of oxide, nitride, and oxynitride materials. The interlayer insulating layer 106 may use a material having a low dielectric constant in order to reduce a coupling phenomenon between wiring lines and, for example, may be formed of flowable oxide (FOX), tonen silazene (TOSZ), undoped silica glass (USG), borosilica glass (BSG), phosphosilica glass (PSG), borophosphosilica glass (BPSG), plasma enhanced tetra ethyl ortho silicate (PRTEOS), fluoride silicate glass (FSG), high density plasma (HDP), plasma enhanced oxide (PEOX), flowable CVD (FCVD) or a combination thereof.

A second metal wiring line 115 is formed in the interlayer insulating layer 106 like the first metal wiring line 110 and also formed at the same level as the first metal wiring line 110. The second metal wiring line 115 may be electrically connected with a device pattern. which can be formed on the substrate. Here, the “same level” means that the layers are formed by the same fabricating process or the same fabricating step or steps.

The first metal wiring line 110 and the second metal wiring line 115 may include, for example, aluminum (Al) or copper (Cu). However, in the semiconductor device embodiments described here, the first metal wiring line 110 and the second metal wiring line 115 include copper.

Copper is an element which is easily diffused so that a diffusion barrier layer may be further provided between the first metal wiring line 110 and the interlayer insulating layer 106 and between the second metal wiring line 115 and the interlayer insulating layer 106. The diffusion barrier layer may include, for example, a material such as Ta, TaN, Ti, TiN, Ru, Co, Ni, NiB, and WN.

In the semiconductor device according to the first embodiment, it is described that the first metal wiring line 110 and the second metal wiring line 115 are formed to be a single layer, for a convenience of description, but the invention is not limited thereto. In other words, a plurality of metal wiring layers may be disposed below the first metal wiring line 110 and the second metal wiring line 115.

In the semiconductor device according to the first embodiment, the first metal wiring line 110 and the second metal wiring line 115 may be a final metal wiring line at a fab-level.

A capping layer 108 may be formed on the first metal wiring line 110, the second metal wiring line 115, and the interlayer insulating layer 106. The capping layer 108 may prevent the first metal wiring line 110 and the second metal wiring line 115 from being oxidized. The capping layer 108 may include, for example, silicon oxynitride (SiON), but is not limited thereto.

A lower passivation layer 130 may be disposed on the capping layer 108. The lower passivation layer 130 includes a trench 132 that exposes the first metal wiring line 110. However, the lower passivation layer 130 covers the second metal wiring line 115 so that the second metal wiring line 115 is not exposed by the lower passivation layer 130. The trench 132 is formed so as to pass through the capping layer 108 formed on the first metal wiring line 110. In FIG. 1, a cross-section of the trench 132 has a trapezoidal shape, but the trench shape is not limited thereto, wherein other shapes may be possible without departing from the present invention.

The lower passivation layer 130 may include, for example, at least one of silicon oxide, silicon nitride, and silicon oxynitride. The lower passivation layer 130 is illustrated as a single layer, but is not limited thereto.

The chip pad 120 may be electrically connected with the first metal wiring line 110. The chip pad 120 may be formed in the trench 132 formed in the lower passivation layer 130. A shape of the chip pad 120 may be dependent on a shape of the trench 132 included in the lower passivation layer 130.

In this embodiment, there is no chip pad 120 which is electrically connected to the second metal wiring line 115. In other words, the first metal wiring line 110 and the second metal wiring line 115 may be distinguished as described below. The chip pad 120 for connection with an external device is electrically connected with the first metal wiring line 110, but the chip pad 120 for connection with the external device is not electrically connected with the second metal wiring line 115.

A top (or upper) surface 120u of the chip pad may be flat. Further, a top (or upper) surface 130u of the lower passivation layer may also be flat. In the semiconductor device according to various embodiments, the top surface 120u of the chip pad and the top surface 130u of the lower passivation layer are flat and disposed in the same plane. In other words, the top surface 120u of the chip pad and the top surface 130u of the lower passivation layer may be coplanar, as shown.

For example, the chip pad 120 may have a substantially uniform thickness and may be formed in the lower passivation layer 130. That is, the top surface 120u of the chip pad may be substantially parallel to a surface corresponding to the top surface 120u of the chip pad, that is, a surface which faces the first metal wiring line 110.

The chip pad 120 may include or be formed from, for example, aluminum, copper, or tungsten. However, in this embodiment, the chip pad 120 includes aluminum.

In accordance with various embodiments of the semiconductor device, the first metal wiring line 110 and the chip pad 120 may include different materials from each other, and specifically, be formed of different materials from each other. That is, in this embodiment, the first metal wiring line 110 and the second metal wiring line 115 include copper and the chip pad 120 includes aluminum.

Aluminum is more tolerable to oxidation than copper, so that when the chip pad 120 is formed of aluminum, the electrical connection between the bump 160 and the chip pad 120 is stable. Further, a hardness of aluminum is higher than that of copper, so that when the chip pad 120 is formed of aluminum, a structure of the bump 160 which is formed above the chip pad 120 is stable.

A first barrier pattern 135 is interposed between the chip pad 120 and the first metal wiring line 110. The first barrier pattern 135 is formed on a bottom surface and a side surface of the trench 132. However, the first barrier pattern 135 is not formed on top surface 130u of the lower passivation layer 130.

The first barrier pattern 135 may function to prevent the material that forms the chip pad 120 from being diffused onto the lower passivation layer 130 and the first metal wiring line 110. Further, the first barrier pattern 135 may function as an adhesive layer that helps the chip pad 120 to be adhered well onto the first metal wiring line 110. The first barrier pattern 135 may include, for example, one of titanium (Ti), titanium nitride (TiN), and combinations thereof.

An upper passivation layer 140 may be disposed on the lower passivation layer 130 and the chip pad 120, e.g., on the chip pad top surface 120u. The upper passivation layer 140 includes a contact hole 142 through which the chip pad 120 is exposed. The upper passivation layer 140 may include, for example, at least one of silicon oxide, silicon nitride, and silicon oxynitride, in various embodiments. The upper passivation layer 140 is illustrated as a single layer, but is not limited thereto. In other embodiments, the upper passivation layer 140 could be or include multiple layers, for example.

In other words, the passivation layers 130 and 140 are formed on the first metal wiring line 110. The passivation layers 130 and 140 include the lower passivation layer 130 and the upper passivation layer 140 which are sequentially laminated on the first metal wiring line 110. The chip pad 120 is enclosed by the passivation layers 130 and 140. The passivation layers 130 and 140 include the trench 132 and the contact hole 142, respectively.

The trench 132 and the contact hole 142 included in the upper passivation layer 140 and the lower passivation layer 130, respectively, are overlaid with each other. Specifically, the first metal wiring line 110, the trench 132, and the contact hole 142 are overlaid with each other, one above the other.

The second barrier pattern 145 is formed on a side wall of the contact hole 142 and a top surface of the upper passivation layer 140 of the passivation layers. Further, the second barrier pattern 145 is formed on the top surface 120u of the chip pad which is exposed through the contact hole 142. Specifically, the second barrier pattern 145 is formed so as to be in contact with the top surface 120u of the chip pad which is exposed through the contact hole 142.

The second barrier pattern 145 may function to prevent the material that forms the bump 160 and the contact 150 from being diffused onto the passivation layers 130 and 140 and the chip pad 120. In contrast, the second barrier pattern 145 may prevent the material, which forms the chip pad 120, from being diffused onto the contact 150. Further, the second barrier pattern 145 may function as an adhesive layer that helps the contact 150 to be adhered well onto the chip pad 120. The second barrier pattern 145 may include, for example, one of titanium, tungsten (W), and a compound thereof

The contact 150 is formed on the second barrier pattern 145. The contact 150 is formed by filling the contact hole 142 in which the second barrier pattern 145 is formed with a conductive material. That is, the contact 150 is formed in the contact hole 142.

The bump 160 is formed on the contact 150. The bump 160 is formed so as to be overlapped with the first metal wiring line 110 and the chip pad 120. The bump 160 is also formed so as to be overlapped with the contact hole 142 and the trench 132. The bump 160 formed on the contact 150 is formed so as to be in contact with the contact 150 and protrudes from and above the upper passivation layer 140. The bump 160 is electrically connected with the chip pad 120, with the contact 150 therebetween.

A shape of the contact 150 may depend on a shape of the contact hole 142. The bump 160 that protrudes from the upper passivation layer 140 may have, for example, a columnar shape. The bump 160 may have one of a cylindrical shape, a truncated cone shape, a polyprism shape, and a truncated polypyramid shape, as examples. In FIG. 1, a side wall 160s of the bump is illustrated to be perpendicular to the top surface of the upper passivation layer 140 for the convenience of description, but the side wall 160s is not limited thereto.

A profile of the side wall 160s of the bump is connected with a profile of a side wall 145s of the second barrier pattern. In other words, the side wall 160s of the bump 160 and the side wall 145s of the second barrier pattern 145 may have a gradient that continuously changes without having a discontinuous point. Specifically, at a point where the bump 160 meets the second barrier pattern 145, the gradient of the side wall 160s of the bump may be substantially equal to the gradient of the side wall 145s of the second barrier pattern.

The contact 150 and the bump 160 may be foamed of the same material, in some embodiments. Further, the contact 150 and the bump 160 may be formed at the same level, in some embodiments. In various embodiments of the semiconductor device, the contact 150 and the bump 160 may include gold (Au). Specifically, the contact 150 and the bump 160 may be formed of gold in some embodiments.

Gold is a material having the highest electrical conductivity. That is, when the bump 160 and the contact 150 are formed of gold, electrical signal exchange may be the most rapidly performed between the external device and the semiconductor device 1. Accordingly, when the semiconductor device including a large number of external terminals exchanges an electrical signal with the external device, the bump and the contact which are formed of gold may be useful. For example, in a semiconductor device that includes a display driver IC (DDI) including a large number of external terminals due to a large number of channels which are connected to the outside (externally), the bump and the contact formed of gold may be useful.

In FIG. 1, a width of the chip pad 120 is a first width w1, a width of the bump 160 is a second width w2, and a width of a lower part of the contact hole 142 is a third width w3.

In the semiconductor device 1 according to the first embodiment, the width w1 of the chip pad 120 is larger than the width w2 of the bump 160. Specifically, the width of the chip pad 120 is larger than the width of the bump 160 so that the bump 160 is entirely overlapped by the chip pad 120.

Further, the second barrier pattern 145 which is interposed between the bump 160 and the upper passivation layer 140 is entirely overlapped by the chip pad 120. In other words, a width of the second barrier pattern 145 is equal to the width w2 of the bump 160 so that the width of the second barrier pattern 145 is smaller than the width w1 of the chip pad 120 and the second barrier pattern 145 is entirely overlapped by the chip pad 120.

The width w3 of the lower part of the contact hole 142 is smaller than the width w1 of the chip pad 120. Therefore, the contact 150 which is formed in the contact hole 142 and the chip pad 120 are stably coupled so as to prevent the contact 150 and the bump 160 from being peeled off.

The contact 150 is formed in the contact hole 142 in which the second barrier pattern 145 is formed so that a width of a lower part of the contact 150 is smaller than the width w3 of the lower part of the contact hole 142 and the width w1 of the chip pad 120.

The contact hole 142 is entirely overlapped by the bump 160. Accordingly, a width of a portion of the contact 150 which is in contact with the bump 160 is smaller than the width w2 of the bump 160.

The width w2 of the bump 160 is formed to be smaller than the width w1 of the chip pad 120 so that a larger number of bumps 160 may be formed on a limited surface of the semiconductor device 1. Further, the bump 160, the chip pad 120, and the first metal wiring line 110 are formed to overlap each other so that a larger number of bumps 160 may be formed on a limited surface of the semiconductor device 1.

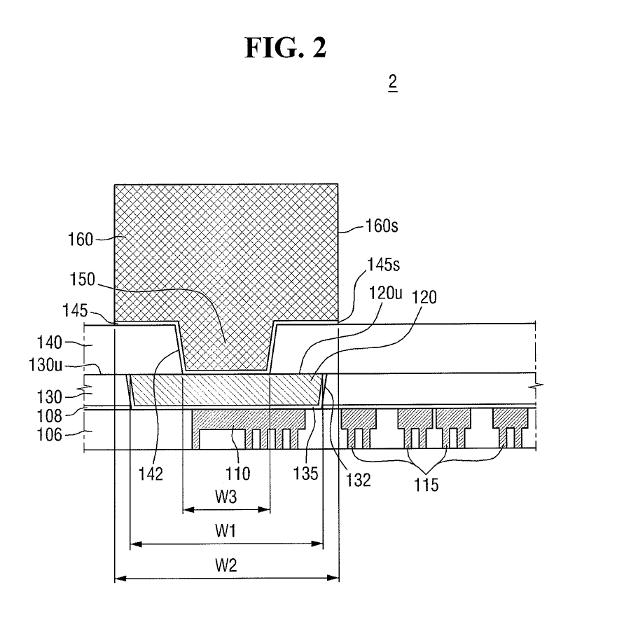

A second embodiment of a semiconductor device according to aspects of the present invention will be described with reference to FIG. 2. The second embodiment is substantially the same as the above-described first embodiment, excepting a relationship between the width of the bump and the width of the chip pad. Therefore, the same components as those of the above-described embodiment will be denoted by the same reference numerals and description thereof will be briefly provided or omitted.

FIG. 2 is a cross-sectional view illustrating a semiconductor device according to a second embodiment. Referring to FIG. 2, a semiconductor device 2 includes a first metal wiring line 110, a chip pad 120, a first barrier pattern 135, a contact 150, and a bump 160.

A width of the chip pad 120 is a first width w1, a width of the bump 160 is a second width w2, and a width of a lower part of a contact hole 142 is a third width w3.

In the semiconductor device 2 according to the second embodiment, the width w1 of the chip pad 120 is smaller than the width w2 of the bump 160. Specifically, the width of the chip pad 120 is smaller than the width of the bump 160 so that the chip pad 120 is entirely overlapped by the bump 160.

Further, the second barrier pattern 145 which is interposed between the bump 160 and the upper passivation layer 140 is also partially overlapped with the chip pad 120. In other words, a width of the second barrier pattern 145 is equal to the width w2 of the bump 160 so that the width of the second barrier pattern 145 is larger than the width w1 of the chip pad 120, and thus the chip pad 120 is entirely overlapped by the second barrier pattern 145.

The width w3 of the lower part of the contact hole 142 is smaller than the width w1 of the chip pad 120. The contact 150 is formed in the contact hole 142 in which the second barrier pattern 145 is formed so that a width of a lower part of the contact 150 is smaller than the width w3 of the lower part of the contact hole 142 and the width w1 of the chip pad 120.

Further, the bump 160, the chip pad 120, and the first metal wiring line 110 are formed to overlap each other so that a larger number of bumps 160 may be formed on a limited surface of the semiconductor device 2.

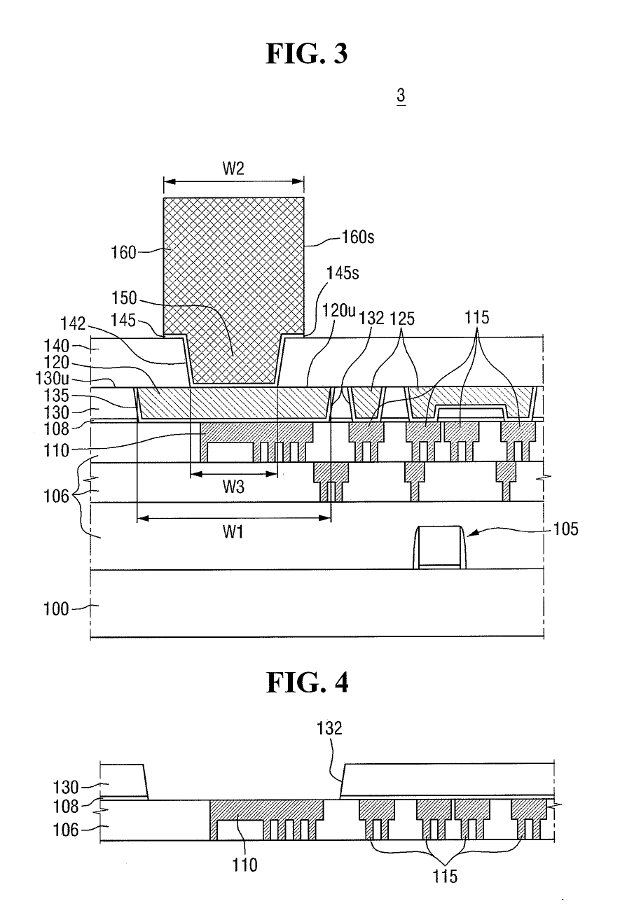

A third embodiment of a semiconductor device according to aspects of the present invention will be described with reference to FIG. 3.

FIG. 3 is a cross-sectional view illustrating a semiconductor device according to a third embodiment. Referring to FIG. 3, a semiconductor device 3 includes a device pattern 105, a first metal wiring line 110, a second metal wiring line 115, a third metal wiring line 125, a chip pad 120, a contact 150, and a bump 160.

The device pattern 105 may be formed in a substrate 100 and/or on the substrate 100. The substrate 100 may be bulk silicon or a silicon-on-insulator (SOI), as examples.

Alternatively, the substrate 100 may be a silicon substrate or include another material, for example, silicon germanium, indium antimonide, a lead telluride compound, indium arsenide, indium phosphate, gallium arsenide, or gallium antimonide, but is not limited thereto.

The device pattern 105 may include a transistor, a diode, or a capacitor, as examples. The device pattern 105 may be configured to be any of a number of circuit devices. Therefore, the semiconductor device 3 may be a semiconductor chip in which a plurality of circuit devices is formed. The circuit device may include a plurality of memory devices and/or logic devices, as examples. The memory device may be, for example, a volatile semiconductor memory device or a non-volatile semiconductor memory device. Various logic devices may be designed in consideration of a function which is performed by the semiconductor device 3.

In FIG. 3, one gate pattern is illustrated as the device pattern 105, but the device pattern 105 is not limited thereto. That is, a plurality of device patterns 105 may be formed, instead of the single gate pattern shown.

The first metal wiring line 110 and the second metal wiring line 115 are disposed on the device pattern 105 and formed at the same level, in this embodiment. The first metal wiring line 110 and the second metal wiring line 115 may be formed in an interlayer insulating layer 106. In addition to the first metal wiring line 110 and the second metal wiring line 115, another metal wiring line may be further disposed between the first metal wiring line 110 and the device pattern 105.

The first metal wiring line 110 may supply, for example, an electrical signal of an external device to the device pattern 105 or supply the electrical signal from the device pattern 105 to the external device. The second metal wiring line 115 may, for example, be a power supply wiring line which supplies a power to the device pattern 105. Alternatively, the second metal wiring line 115 may be a wiring line which is used by the device pattern 105 in order to receive or supply the electrical signal, e.g., a logic signal.

A capping layer 108 may be disposed on the first metal wiring line 110, the second metal wiring line 115, and the interlayer insulating layer 106.

The chip pad 120 and the third metal wiring line 125 are formed on the first metal wiring line 110 and the second metal wiring line 115. The chip pad 120 is electrically connected with the first metal wiring line 110 and the third metal wiring line 125 is electrically connected with the second metal wiring line 115.

The chip pad 120 and the third metal wiring line 125 may be formed in a lower passivation layer 130 and formed at the same level, in this embodiment. Like the chip pad 120 which is formed in a trench 132 included in the lower passivation layer 130, the third metal wiring line 125 is also formed in the trench 132 which is included in the lower passivation layer 130. Further, the third metal wiring line 125 is formed at the same level as the chip pad 120 so that the third metal wiring line 125 may include aluminum.

A top surface 120u of the chip pad and a top surface 130u of the lower passivation layer are flat and disposed on the same plane, in this embodiment.

The third metal wiring line 125 may be electrically connected with one second metal wiring line 115, or electrically connect a plurality of second metal wiring lines 115. For example, when the second metal wiring line 115 is a power supply wiring line which supplies a power to the device pattern 105, the third metal wiring line 125 may serve as a connection wiring line between the power supply wiring lines.

A barrier pattern is formed of the same material as the first barrier pattern 135 between the third metal wiring line 125 and the lower passivation layer 130.

An upper passivation layer 140 may be disposed on the lower passivation layer 130, the chip pad 120, and the third metal wiring line 125. The upper passivation layer 140 includes a contact hole 142 through which the chip pad 120 is exposed. However, the upper passivation layer 140 covers the third metal wiring line 125, so that the third metal wiring line 125 is not exposed.

The trench 132 and the contact hole 142 which are included in the upper passivation layer 140 and the lower passivation layer 130, respectively, overlap each other. Specifically, the first metal wiring line 110, the trench 132, and the contact hole 142 are overlapped with each other.

The second barrier pattern 145 is formed on a side wall of the contact hole 142 and a top surface of the upper passivation layer 140 of the passivation layers.

The contact 150 is formed on the second barrier pattern 145 by filling the contact hole 142 with a conductive material. The contact 150 is formed in the contact hole 142.

The bump 160 is formed on the contact 150. The bump 160 is formed to be overlapped with the first metal wiring line 110 and the chip pad 120. The bump 160 is also formed to be overlapped with the contact hole 142 and the trench 132. The bump 160, which is formed on the contact 150, is formed to be in contact with the contact 150 and protrudes from the upper passivation layer 140, e.g., above the upper passivation layer 140. The bump 160 is electrically connected with the chip pad 120 via the contact 150 therebetween.

A profile of a side wall 160s of the bump is connected with a profile of a side wall 145s of the second barrier pattern. Here, the profiles are corresponding profiles that can directly contact each other in a conformal manner.

In FIG. 3, a width of the chip pad 120 is a first width w1, a width of the bump 160 is a second width w2, and a width of a lower part of the contact hole 142 is a third width w3.

In FIG. 3, it is illustrated that the width w1 of the chip pad 120 is larger than the width w2 of the bump 160 and the bump 160 is entirely overlapped with the chip pad 120, but the present invention is not limited thereto. That is, it is sufficient if the width w3 of the lower part of the contact hole 142 is smaller than the width w1 of the chip pad 120, and similarly to the second embodiment of the present invention, the width w1 of the chip pad 120 may be smaller than the width w2 of the bump 160.

An embodiment of a method for fabricating a semiconductor device according to aspects of the present invention will be described with reference to FIGS. 1 and 4 to 10.

FIGS. 4 to 10 are diagrams illustrating embodiments of intermediate processes of a method for fabricating a semiconductor device according to an embodiment of the present invention.

Referring to the embodiment of FIG. 4, a lower passivation layer 130 is formed on a first metal wiring line 110 and a second metal wiring line 115. The lower passivation layer 130 includes a trench 132 that exposes the first metal wiring line 110.

Specifically, an interlayer insulating layer 106 can be formed on a substrate on which a device pattern is formed. The interlayer insulating layer 106 may include, for example, at least one of oxide, nitride, and oxynitride. A pattern for forming the first metal wiring line and the second metal wiring line 115 is formed in the interlayer insulating layer 106. A conductive material is filled in the patterned interlayer insulating layer 106 and the conductive material is planarized until the interlayer insulating layer 106 is exposed. By doing this, the first metal wiring line 110 and the second metal wiring line 115 are formed in the interlayer insulating layer 106. For example, when the first metal wiring line 110 and the second metal wiring line 115 are formed of copper, a method that forms the first metal wiring line 110 and the second metal wiring line 115 in the interlayer insulating layer 106 may be a damascene process, as an example.

After forming the first metal wiring line 110 and the second metal wiring line 115, a capping layer 108 and a lower passivation layer 130 which cover the first metal wiring line 110 and the second metal wiring line 115 are formed. Thereafter, the lower passivation layer 130 and the capping layer 108 are patterned to than the trench 132 which exposes the first metal wiring line 110.

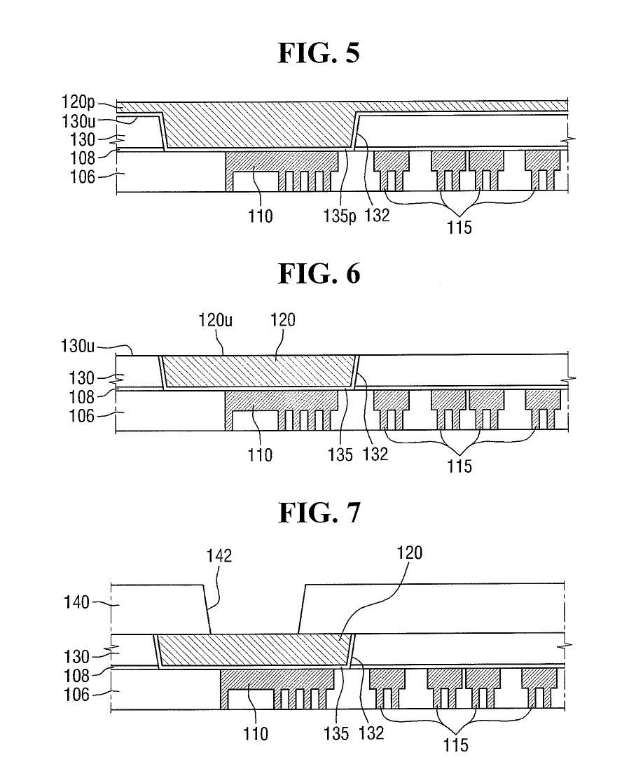

Referring to the embodiment of FIG. 5, a first barrier layer 135p is formed on the trench 132 and the lower passivation layer 130. A conductive layer 120p, which fills the trench 132 in which the first barrier layer 135p is formed, is formed on the lower passivation layer 130.

Specifically, the first barrier layer 135p is formed on a side surface and a bottom surface of the trench 132. The first barrier layer 135p is formed to extend to a top surface 130u of the lower passivation layer. The first barrier layer 135p may be conformally formed on the top surface 130u of the lower passivation layer and in the trench 132. The first barrier layer 135p may be formed on the bottom surface of the trench 132 so as to be in contact with the first metal wiring line 110 exposed through the trench 132.

The first barrier layer 135p may include, for example, one of titanium (Ti), titanium nitride (TiN), and combinations thereof. The first barrier layer 135p may be formed using, for example, one of a chemical vapor deposition method, a sputtering method, and a physical vapor deposition method, as examples.

After forming the first barrier layer 135p, a first seed metal layer may be formed on the first barrier layer 135p so as to form a conductive layer 120p. The first seed metal layer for forming the conductive layer 120p may include, for example, the same material as the conductive layer 120p, and specifically, include aluminum. The first seed metal layer for forming the conductive layer 120p may be formed, for example, using one of the sputtering method and the physical vapor deposition method.

After forming the first seed metal layer on the first barrier layer 135p, the conductive layer 120p is formed on the first barrier layer 135p using a first electroplating method, in this embodiment. The conductive layer 120p fills the trench 132 in which the first barrier layer 135p is formed and is also formed on the top surface 130u of the lower passivation layer.

The conductive layer 120p may include, for example, aluminum. The conductive layer 120p may be formed, as an example, by soaking a substrate in an electroplating solution which includes aluminum ions. The first seed metal layer is formed in the trench 132 and on the top surface 130u of the lower passivation layer so that conductive layer 120p fills the trench 132 and is also formed on the top surface of the lower passivation layer 130.

Referring to the embodiment of FIG. 6, the conductive layer 120p is planarized to expose the top surface 130u of the lower passivation layer. By doing this, the chip pad 120 is formed in the lower passivation layer 130.

The conductive layer 120p which is formed on the top surface 130u of the lower passivation layer is removed by a planarization process (CMP). When the conductive layer 120p which is formed on the top surface 130u of the lower passivation layer is removed, the first barrier layer 135p which is formed on the top surface 130u of the lower passivation layer is also removed. The planarization process is performed until the top surface 130u of the lower passivation layer is exposed.

When the top surface 130u of the lower passivation layer is exposed, the chip pad 120 is formed in the lower passivation layer 130, and specifically, in the trench 132. In this case, a first barrier pattern 135 is also formed between the chip pad 120 and the lower passivation layer 130. The first barrier pattern 135 is formed on the side surface and the bottom surface of the trench 132, but is not formed on the top surface 130u of the lower passivation layer.

The first barrier pattern 135 is formed to be in contact with the first metal wiring line 110 which is disposed therebelow so that the chip pad 120 which is formed in the trench 132 is also electrically connected with the first metal wiring line 110. The chip pad 120 is formed on the first metal wiring line 110 and overlaid with the first metal wiring line 110.

The chip pad 120 is formed by the planarization process so that a top surface 120u of the chip pad and the top surface 130u of the lower passivation layer are disposed in the same plane.

Referring to the embodiment of FIG. 7, an upper passivation layer 140 is formed on the chip pad 120 and the lower passivation layer 130. The upper passivation layer 140 includes a contact hole 142 through which the chip pad 120 is exposed.

The upper passivation layer 140 is formed on the lower passivation layer 130 on which the chip pad 120 is formed. Thereafter, the upper passivation layer 140 is patterned to form the contact hole 142 through which the chip pad 120 is exposed.

The contact hole 142 is entirely overlaid with the chip pad 120. That is, a width of a lower part of the contact hole 142 is smaller than a width of the chip pad 120. The contact hole 142 exposes only a part of the chip pad 120 so that a part of the chip pad 120 is exposed through the contact hole 142 and the remaining part of the chip pad 120 is covered with the upper passivation layer 140.

The contact hole 142 which is formed in the upper passivation layer 140 is entirely overlapped by the trench 132 formed in the lower passivation layer 130.

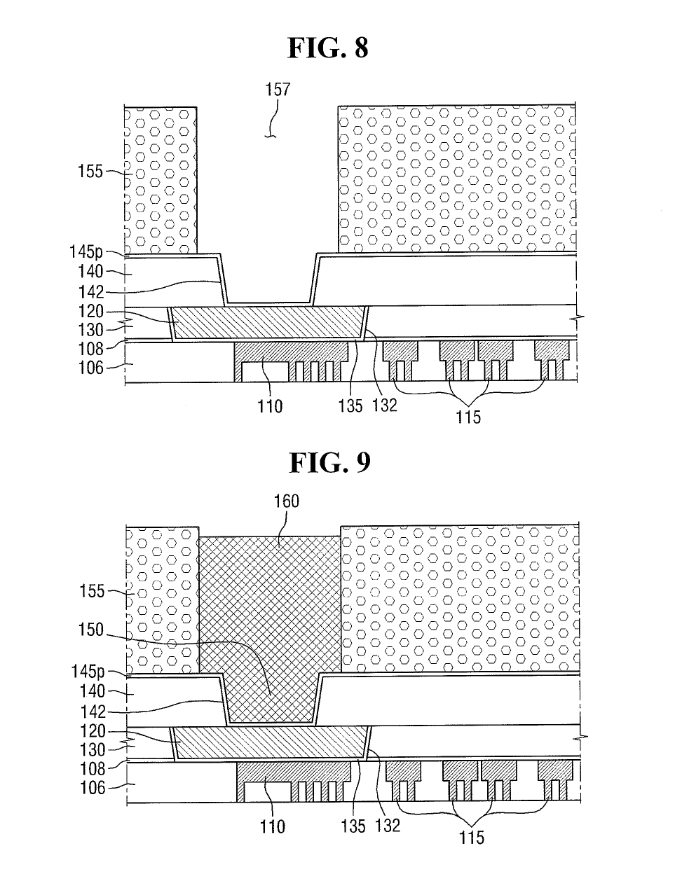

Referring to the embodiment of FIG. 8, a second barrier layer 145p is formed on a side wall of the contact hole 142 and a top surface of the upper passivation layer 140. Thereafter, a blocking pattern 155 is formed on the upper passivation layer 140 on which the second barrier layer 145p is formed. The blocking pattern 155 includes an opening 157 which is overlapped with the contact hole 142.

Specifically, the second barrier layer 145p is formed on a side surface of the contact hole 142. The second barrier layer 145p is formed to extend onto the top surface of the upper passivation layer 140. The second barrier layer 145p may be conformally formed on the top surface of the upper passivation layer 140 and in the contact hole 142. The second barrier layer 145p is formed on the chip pad 120 which is exposed through the contact hole 142. The second barrier layer may be formed to be in contact with the chip pad 120, which is exposed through the contact hole 142.

The second barrier layer 145p may include, for example, one of titanium, tungsten (W), and a compound thereof. The second barrier layer 145p may be formed using, for example, one of a chemical vapor deposition method, a sputtering method, and a physical vapor deposition method.

After forming the second barrier layer 145p, a second seed metal layer may be formed on the second barrier layer 145p. The second seed metal layer may include, for example, the same material as the contact which will be subsequently formed, and specifically, include gold. The second seed metal layer may be formed using, for example, one of the sputtering method and the physical vapor deposition method.

After forming the second seed metal layer on the second barrier layer 145p, a blocking layer is formed on the second barrier layer 145p. The blocking layer may be, for example, a photo resist, but is not limited thereto. Thereafter, a part of the blocking layer is removed to form an opening 157. By doing this, the blocking pattern 155 is formed on the second barrier layer 145p.

The opening 157 overlaps the contact hole 142. Specifically, a width of the opening 157 is larger than a width of the contact hole 142 so that the contact hole 142 is entirely overlapped by the opening 157. Not only the second barrier layer 145p which is formed in the contact hole 142 but also a part of the second barrier layer 145p which is formed on the top surface of the upper passivation layer 140 are exposed through the opening 157.

In FIG. 8, it is illustrated that the width of the opening 157 is smaller than the width of the chip pad 120, but the present invention is not limited thereto. In other words, the width of the opening 157 may vary depending on a width of a bump (160 in FIG. 9) which is included in the semiconductor device.

Referring to the embodiment of FIG. 9, the bump 160 which is overlapped by the chip pad 120 and the first metal wiring line 110 is formed using a second electroplating method.

When the bump 160 is formed using the second electroplating method, the contact hole 142 in which the second barrier layer 145p is formed is filled with a conductive material to simultaneously form the contact 150. The contact 150 and the bump 160 are electrically connected with the chip pad 120.

Specifically, the contact hole 142 and the opening 157 are filled with the conductive material using the second electroplating method, which forms the contact 150 and bump 160, in this embodiment. The conductive material may include, for example, gold. The substrate is soaked in the electroplating solution which includes gold ions so that the contact hole 142 and the opening 157 are filled with the conductive material and thus the contact 150 and the bump 160 are &tined. The contact 150 and the bump 160 can include the same material, and specifically, can include or be formed from gold.

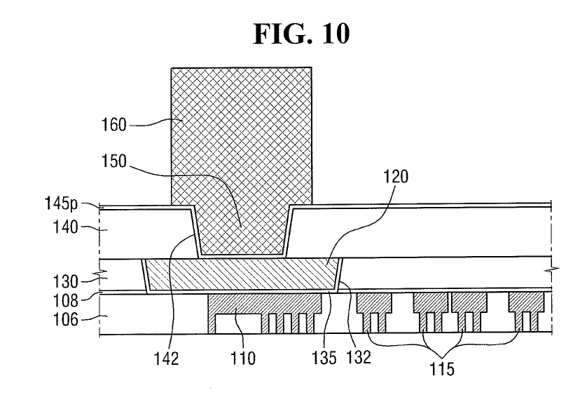

Referring to FIGS. 1 and 10, after forming the contact 150 and the bump 160, the blocking pattern 155 is removed. After removing the blocking pattern 155, the bump 160 can be used as an etching mask to pattern the second barrier layer 145p.

The blocking pattern 155 may be, for example, ashed or stripped to be removed. After removing the blocking pattern 155, the second barrier layer 145p is divided into a portion which is overlaid with the bump 160 and a portion which is not overlapped with the bump 160. The bump 160 needs to be electrically separated from bumps which may be formed around the bump 160 so that the second barrier layer 145p which is not overlapped with the bump 160 needs to be removed. The second barrier layer 145p which is not overlapped with the bump 160 may be removed, for example, by an etching process, and specifically, by a dry etching process. The top surface of the upper passivation layer 140 is exposed by removing the second barrier layer 145p which is not overlapped with the bump 160.

The second barrier layer 145p is patterned to form a second barrier pattern 145. The second barrier layer 145p is patterned by the dry etching process so that a profile of a side wall of the bump 160 may be connected with a profile of a side wall of the second barrier pattern 145.

In the embodiment of a method for fabricating a semiconductor device according to aspects of the present invention, it is not described that the third metal wiring line (125 in FIG. 3), which is electrically connected with the second metal wiring line 115 and framed at the same level as the chip pad 120, is formed. However, referring to FIGS. 4 to 6, after additionally forming a trench, which exposes the second metal wiring line 115, in the lower passivation layer 130, the trench which exposes the second metal wiring line 115 may be filled using the first electroplating method. In this case, it would be understood by those skilled in the art that the third metal wiring line (125 in FIG. 3) may be formed.

The foregoing is illustrative of the present invention and are not to be construed as limiting thereof. Although a few embodiments in accordance with aspects of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing specific embodiments are illustrative and are not to be construed as limiting the present invention, and that modifications to the disclosed embodiments, as well as other embodiments, are intended to be included within the scope of the appended claims. The present invention is defined by the following claims, with equivalents of the claims to be included therein.

1. A semiconductor device, comprising:
a first metal wiring line;
a chip pad electrically connected with the first metal wiring line and having a first width;
a passivation layer that encloses the chip pad and includes a contact hole;
a first barrier pattern formed on a side wall of the contact hole and a top surface of the passivation layer;
a contact filling the contact hole on the first barrier pattern; and
a bump which is formed of the same material as the contact, wherein the bump has a second width which is smaller than the first width, and is overlaid with the first metal wiring line and the chip pad, the bump being entirely overlapped by the chip pad.

2. The semiconductor device of claim 1, wherein a profile of a side wall of the first barrier pattern is connected with a profile of a side wall of the bump.

3. The semiconductor device of claim 1, wherein the bump and the contact include gold.

4. The semiconductor device of claim 1, further comprising:
a second metal wiring line formed at the same level as the first metal wiring line; and
a third metal wiring line formed at the same level as the chip pad,
wherein the third metal wiring line is electrically connected with the second metal wiring line.

5. The semiconductor device of claim 4, further comprising:
a device pattern formed below the first metal wiring line and the second metal wiring line,
wherein the second metal wiring line is a power supply wiring line supplying a power to the device pattern.

6. The semiconductor device of claim 1, wherein the passivation layer includes a lower passivation layer and an upper passivation layer sequentially laminated on the first metal wiring line, and
wherein the chip pad is formed in the lower passivation layer and the contact hole is formed in the upper passivation layer.

7. The semiconductor device of claim 6, wherein a top surface of the lower passivation layer and a top surface of the chip pad are coplanar.

8. The semiconductor device of claim 1, wherein the first metal wiring line and the chip pad are formed of different materials from each other.

9. The semiconductor device of claim 8, wherein the first metal wiring line includes copper (Cu) and the chip pad includes aluminum (Al).

10. A semiconductor device, comprising:
a device pattern;
a first metal wiring line and a second metal wiring line which are disposed on the device pattern and formed at the same level;
a chip pad which is electrically connected with the first metal wiring line, has a first width, and has a flat top surface;
a third metal wiring line which is electrically connected with the second metal wiring line and formed at the same level as the chip pad; and
a bump which is electrically connected with the chip pad, has a second width which is smaller than the first width, and is overlapped by the first metal wiring line and the chip pad.

11. The semiconductor device of claim 10, wherein the second metal wiring line is a power supply wiring line supplying a power to the device pattern.

12. The semiconductor device of claim 10, further comprising:
an upper passivation layer disposed on the chip pad and the third metal wiring line,
wherein the bump protrudes from the upper passivation layer.

13. The semiconductor device of claim 12, further comprising:
a contact interposed between the chip pad and the bump,
wherein the contact is formed in the upper passivation layer and the contact and the bump are formed at the same level.

14. The semiconductor device of claim 13, wherein the bump and the contact are formed of gold.

15.-20. (canceled)
